(19) United States
(12) Patent Application Publication
(10) Pub. No.: US 2020/0255971 A1
(43) Pub. Date: Aug. 13, 2020

(54) METHODS FOR RECYCLING MONOCRYSTALLINE SEGMENTS CUT FROM A MONOCRYSTALLINE INGOT

(71) Applicant: Corner Star Limited, Kowlpon (HK)

(72) Inventor: Steven Lawrence Kimbel, ST. Charles, MO (US)

(21) Appl. No.: 15/776,357

(22) PCT Filed: Nov. 18, 2016
(86) PCT No.: PCT/US2016/062801

§ 371 Date: May 15, 2018

(51) Int. Cl. C30B 15/02; C30B 15/12; C30B 15/20; C30B 29/06

(52) U.S. Cl. CPC C30B 15/02; C30B 15/12; C30B 15/36; C30B 29/06; C30B 15/20

(57) ABSTRACT

A method of recycling monocrystalline segments cut from a monocrystalline ingot of semiconductor or solar grade material is provided. The method includes removing a first monocrystalline segment from the monocrystalline ingot, connecting the first monocrystalline segment to a second monocrystalline segment to form a chain of monocrystalline segments, and introducing the chain of monocrystalline segments into a melt of semiconductor or solar grade material.

### CROSS-REFERENCE TO RELATED APPLICATIONS

This application claims priority to U.S. Provisional Patent Application Ser. No. 62/256,776, filed 18 Nov. 2015, the disclosure of which is hereby incorporated by reference in its entirety.

### FIELD

The field of the disclosure relates generally to methods and systems for producing ingots of semiconductor or solar grade material from a melt and, more particularly, to methods for recycling monocrystalline segments cut from a monocrystalline ingot.

### BACKGROUND

In the production of silicon crystals grown by the continuous Czochralski (CCZ) method, polycrystalline silicon is first melted within a crucible, such as a quartz crucible, of a crystal pulling device to form a silicon melt. The puller then lowers a seed crystal into the melt and slowly raises the seed crystal out of the melt extracting a monocrystalline ingot or boule from the melt. As the silicon crystal is grown from the melt, polycrystalline silicon is added to the melt to replenish the silicon that is incorporated into the growing crystal. The monocrystalline ingot or boule is then cut into segments (or smaller ingots) for ease in handling and machined into wafers, which can be used in a variety of electronic or solar components.

In some applications, such as solar applications, monocrystalline ingots are processed by removing axial slabs or segments along certain crystallographic directions (e.g., along <110> directions) to form square, almost-full-square, or pseudo-square monocrystalline ingots. These segments are colloquially referred to as “wing” segments. The remaining ingots can then be further processed into wafers. There are typically four wing segments per ingot, and the total amount of material removed with the wing segments can be in excess of 20%, sometimes around 30%, of the original monocrystalline ingot volume.

At least some methods for recycling wing segments include processing (e.g., hammering or comminuting) the wing segments into feedable or flowable silicon feedstock material, and feeding the material into the melt via a granular feed system. However, there are several drawbacks to recycling wing segments in this manner. For example, a volume fraction of the original wing segment is lost because of the amount of processing required. Additionally, feedstock material prepared from recycled wing segments often has a rod- or needle-like shape because of the cleave planes of the monocrystalline structure of the wing segments. As a result, feedstock material prepared from wing segments may require additional size processing to inhibit bridging and blocking feed paths by such high aspect ratio silicon granules, which may increase the contamination rate of the feedstock material and, consequently, melt and crystal contamination. Contamination from silicon feedstock may be removed by etching, but etching generally increases costs, processing time, labor, and energy associated with recycling the wing segments. Generally the processing of silicon feedstock into small pieces adds significant costs, processing time, labor, energy, safety risk, blockage risk, and/or contamination risk of the feedstock material for the CCZ process.

Other methods of recycling monocrystalline wing segments include minimal size processing of the wing segments to produce relatively large feedstock pieces, and feeding the larger silicon feedstock material into a melt. However, use of larger feedstock generates relatively large splashes in the melt, increasing hot zone contamination and locally reducing temperature of the melt. Other drawbacks of using relatively large feedstock pieces include the risk of electrical arcing, graphite conversion and damage, vibrations within the system, crucible rotation seizing, and even crucible breakage.

Accordingly, a need exists for a more efficient method for recycling monocrystalline wing segments.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

In one aspect, a method of recycling monocrystalline segments cut from a monocrystalline ingot of semiconductor or solar grade material includes removing a first monocrystalline segment from the monocrystalline ingot, connecting the first monocrystalline segment to a second monocrystalline segment to form a chain of monocrystalline segments, and introducing the chain of monocrystalline segments into a melt of semiconductor or solar grade material.

In another aspect, a method of growing a monocrystalline ingot from a melt of semiconductor or solar grade material includes preparing the melt of semiconductor or solar grade material in a crucible assembly including a fluid barrier separating the melt into an inner melt zone and an outer melt zone, pulling a monocrystalline ingot from the inner melt zone, and introducing a chain of interconnected monocrystalline segments into the outer melt zone to replenish the melt as the ingot is pulled from the melt.

In yet another aspect, a method of forming granular silicon pieces of semiconductor or solar grade material includes preparing a melt of semiconductor or solar grade material in a crucible assembly including an inner crucible, introducing at least one chain of interconnected monocrystalline segments into the inner crucible to initiate a flow of the melt out of the inner crucible, forming a melt droplet from the flow of the melt, and cooling the melt droplet to form a granular silicon piece of semiconductor or solar grade material.

In yet another aspect, a chain of monocrystalline segments of semiconductor or solar grade material includes a first monocrystalline segment and a second monocrystalline segment. The first monocrystalline segment includes a first end, an opposing second end, and a first connection interface disposed at one of the first and second ends. The second monocrystalline segment includes a first end, an opposing second end, and a second connection interface disposed at one of the first and second ends. The first monocrystalline segment is connected to the second monocrystalline segment via the first and second connection interfaces.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a side view of a monocrystalline ingot;

FIG. 2 is a perspective view of a portion of the ingot shown in FIG. 1 subsequent to a slicing operation in which monocrystalline wing segments are sliced from the ingot;

FIG. 3 is a perspective view of one of the wing segments cut from the ingot shown in FIG. 2;

FIG. 4 is a front view of a chain of interconnected monocrystalline wing segments showing one embodiment of a connection interface for interconnecting the wing segments shown in FIG. 2;

FIG. 5 is a front view of a chain of interconnected monocrystalline wing segments showing a second embodiment of a connection interface for interconnecting the wing segments shown in FIG. 2;

FIG. 6 is a front view of a chain of interconnected monocrystalline wing segments showing a third embodiment of a connection interface for interconnecting the wing segments shown in FIG. 2;

FIG. 7 is a schematic cross-section of a crystal growing system including a system for recycling the wing segments shown in FIG. 2; and

FIG. 8 is a schematic cross-section of a granular silicon production system including a system for recycling the wing segments shown in FIG. 2.

Corresponding reference characters indicate corresponding parts throughout the several views of the drawings.

### DETAILED DESCRIPTION

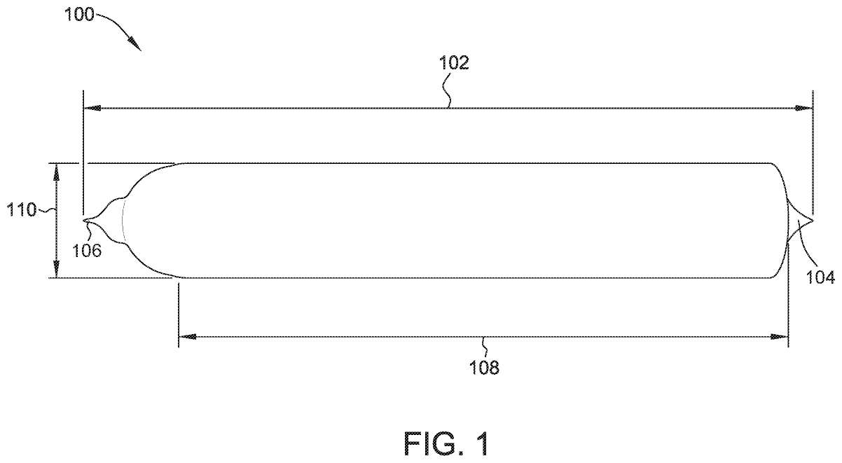

Referring to FIG. 1, a monocrystalline boule or ingot as typically grown by a Czochralski method is indicated generally at 100. The ingot 100 has an axial length 102 extending from a seed end 104 to an opposite or tail end 106. Additionally, the ingot 100 has a constant diameter portion 108 with a diameter 110.

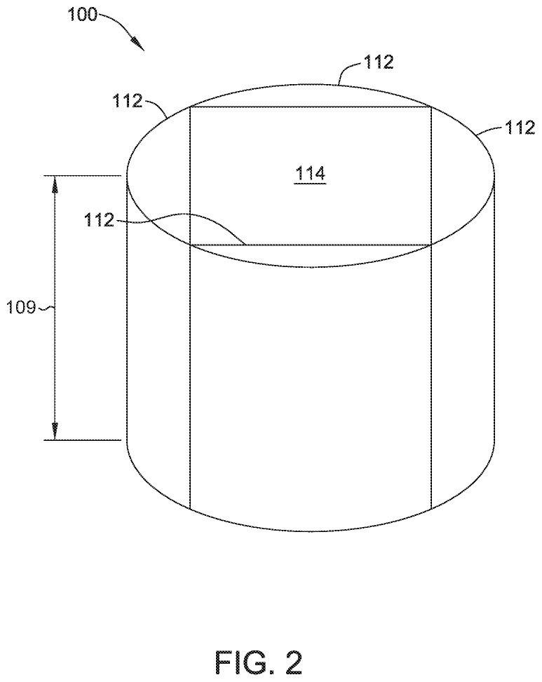

With additional reference to FIG. 2, the monocrystalline ingot 100 can be processed by removing the seed end 104 and the tail end 106. Additionally, the constant diameter portion 108 can also be cut into one or more segments 109 having a length capable of fitting within a slicing saw. In some embodiments, the constant diameter portion 108 has a length of between about 0.5 meters to about 5 meters, and the segments 109 cut from the constant diameter portion 108 have a length of less than 1 meter, and, more suitably, less than 0.5 meters. In some embodiments, the constant diameter portion 108 is cut into multiple segments 109.

Furthermore, as shown in FIG. 2, the ingot 100 can be processed by removing four monocrystalline wing segments 112 from the <110> directions, leaving a rectangular or nearly rectangular monocrystalline segment 114. In the example embodiment, the rectangular segment 114 has a cross-section of a square. In alternative embodiments, the rectangular segment 114 is almost-full-square or pseudo-square (e.g., a square with rounded corners). The rectangular segment 114 can be further processed into wafers of semiconductor or solar material.

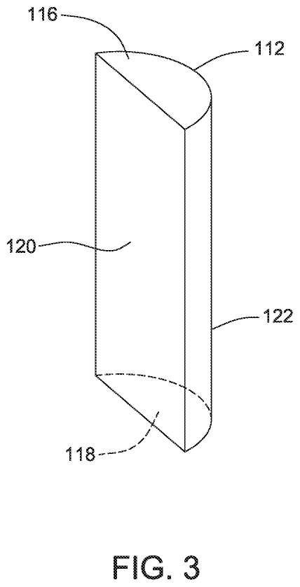

Referring to FIG. 3 the wing segments 112 are generally semi-cylindrical, curved segments as shown in FIG. 3, and monocrystalline after being produced in the Czochralski or continuous Czochralski process. In the example embodiment, each wing segment includes a first end 116, an opposing second end 118, a planar surface 120 extending from the first end 116 to the second end 118, and an arcuate surface 122 opposite the planar surface 120 and extending between the first end 116 and the second end 118. In other embodiments, the wing segments 112 may have shapes other than that shown in FIG. 3. The wing segments 112 may have any suitable length that enables the systems and methods to function as described herein including, for example and without limitation, up to 3 meters, up to 4 meters, and even lengths greater than 4 meters.

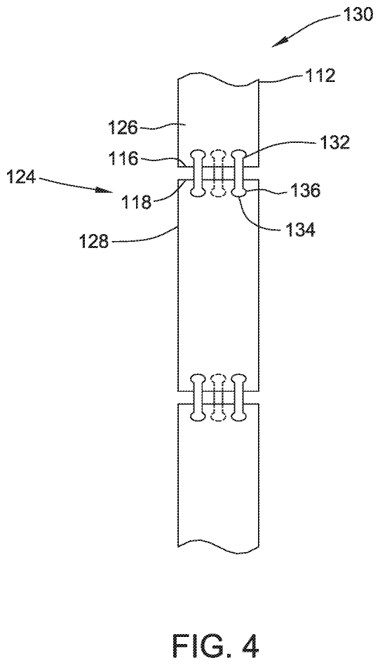

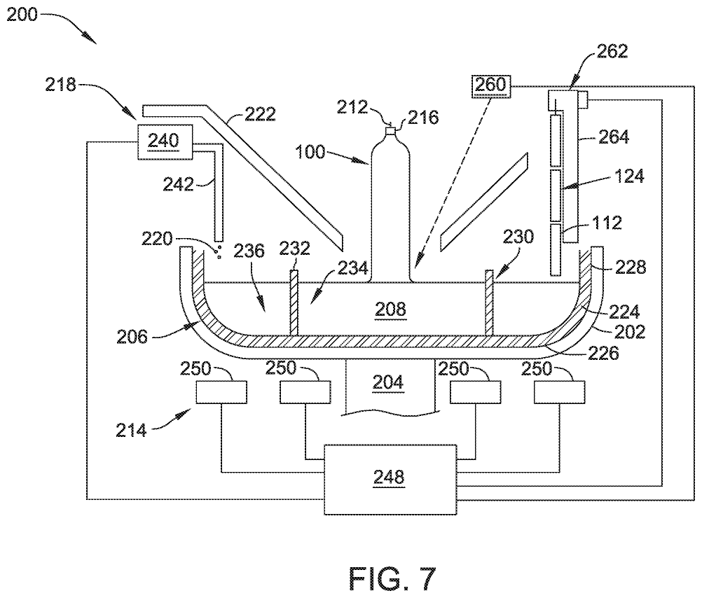

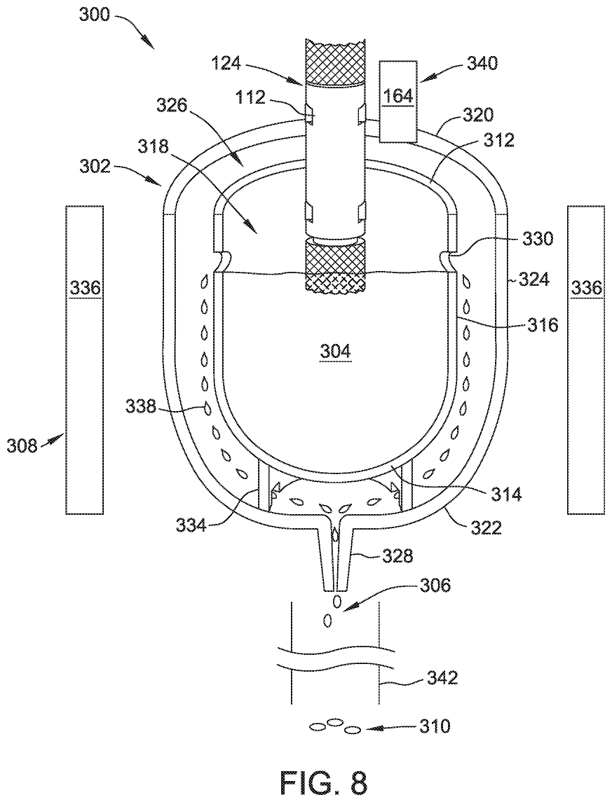

Referring to FIGS. 4-6, in embodiments of the present disclosure, the monocrystalline wing segments 112 removed from the monocrystalline ingot 100 are recycled by connecting a plurality of wing segments 112 together to form a chain 124 of monocrystalline wing segments, and introducing the chain 124 into a melt of semiconductor or solar grade material. Methods of introducing the chain 124 of monocrystalline wing segments are described in more detail herein with reference to FIGS. 7 and 8.

In some embodiments, the wing segments 112 are cleaned and etched prior to being connected to one another to form the chain 124 of monocrystalline wing segments. Suitable processes for cleaning and etching the wing segments 112 include, for example and without limitation, pure abrasive removal of steel-wire cut surfaces by silicon-carbide (SiC) grinding, soap washing, and clean water rinsing, or one or more chemical treatments that dissociate surface metals. Suitable chemical treatments include, for example and without limitation, hot potassium hydroxide baths, Mixed Acid Etchant (MAE) baths, where MAE is a mixture of nitric acid, hydroflouric acid, and acetic acid in one of various commercially available volume formulations, such as, but not limited to, 6:1:1, 4:1:2, 3:1:2, 2:1:1, 5:3:3, and 2:2:1, depending on the desired etching rate. Chemical treatments may be followed by water rinsing to dilute residual surface chemicals.

To interconnect two or more wing segments 112, a first connection interface 126 is formed at the first end 116 of the wing segment 112, and a second connection interface 128 is formed at the second end 118 of the wing segment 112. The first connection interface 126 and second connection interface 128 interconnect or interlock with one another, thereby forming the chain 124 of monocrystalline wing segments. The chain 124 may include any suitable number of wing segments 112, including, for example and without limitation, two, three, four, five, ten, or more wing segments.

FIG. 4 shows one embodiment of an interconnection system 130 suitable for connecting two or more monocrystalline wing segments 112 to form a chain 124. In the interconnection system 130 shown in FIG. 4, the first connection interface 126 includes a first notch 132, and the second connection interface 128 includes a second notch 134. Each of the first notch 132 and the second notch 134 extends axially inward from one of the first end 116 and the second end 118 of a corresponding wing segment 112. An interconnecting member 136 formed separately from the wing segments 112 is used to connect the two wing segments 112 together. More specifically, a first end of the interconnecting member 136 is inserted into the first notch 132 and a second end of the interconnecting member 136 is inserted into the second notch 134. The interconnecting member connects each wing segment 112 together, thereby forming the chain 124 of monocrystalline wing segments. In some embodiments, the interconnecting member 136 is formed of polycrystalline silicon or monocrystalline silicon. In other embodiments, the interconnecting member 136 may be formed of any suitable material or materials.

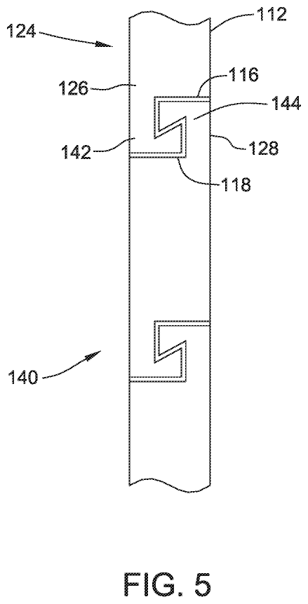

FIG. 5 shows a second embodiment of an interconnection system 140 suitable for connecting two or more monocrystalline wing segments 112 together to form a chain 124. In the interconnection system 140 shown in FIG. 5, the first connection interface 126 includes a first hook 142, and the second connection interface 128 includes a second hook 144 configured to matingly engage the first hook 142. In use, the first hook 142 and the second hook 144 matingly engage one another to form the chain 124 of monocrystalline wing segments.

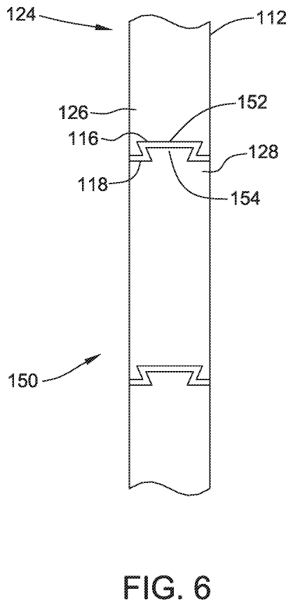

FIG. 6 shows a third embodiment of an interconnection system 150 suitable for connecting two or more monocrystalline wing segments 112 together to form a chain 124. In the interconnection system 150 shown in FIG. 6, the second connection interface 128 includes a tongue 154 protruding outward from one of the first and second ends 116 and 118 of the wing segment 112, and the first connection interface 126 includes a groove 152 extending axially inward into the wing segment 112 from one of the first and second ends 116 and 118. The tongue 154 and groove 152 are sized and shaped complementary to one another such that the tongue 154 and groove 152 matingly engage with each other to form the chain 124 of monocrystalline wing segments. In other embodiments, two or more wing segments 112 may be connected together using any suitable connection system that enables the wing segments 112 to be connected together to form a chain 124 of monocrystalline wing segments. The connection interfaces may be formed, for example, by grinding or cutting. In some embodiments, for example, the connection interfaces are formed using a wire saw with a wire moving in a patterned parallel path to minimize material loss. The small removed pieces may be utilized in initial charges or by other feeding means.

Monocrystalline wing segments 112 cut from the monocrystalline ingot 100 are recycled by introducing the wing segments 112 back into a melt of semiconductor or solar grade material. A first wing segment 112 is removed from the monocrystalline ingot 100. The first wing segment 112 is connected to a second wing segment 112 forming the chain 124 of monocrystalline segments. This chain 124 is introduced into a melt of semiconductor or solar grade material such as the melt 208 described in more detail herein with reference to FIG. 7 and the melt 304 described in more detail herein with reference to FIG. 8. More specifically, the first wing segment 112 is interlocked with the second wing segment 112 forming the chain 124. Even more specifically, the first connection interface 126 is formed at the first end 116 of the first wing segment 112 and the second connection interface 128 is formed at the second end 118 of the second wing segment 112 such that the first connection interface 126 and the second connection interface 128 interlock. For example, the first connection interface 126 is formed with the first hook 142 and the second connection interface 128 is formed with the second hook 144 which matingly engage each other. In other embodiments, the first connection interface 126 is formed with the groove 152 and the second connection interface 128 is formed with the tongue 154 which matingly engage each other. In yet other embodiments, the first connection interface 126 is formed with the first notch 132 and the second connection interface 128 is formed with the second notch 134 which are connected by an interconnecting member inserted within each notch.

Referring to FIG. 7, a crystal growing system suitable for recycling monocrystalline wing segments 112 is shown schematically and is indicated generally at 200. The crystal growing system 200 is used to produce monocrystalline ingots 100 by a Czochralski method. As discussed herein, the system is described in relation to the continuous Czochralski method of producing ingots, though a batch process may be used. For example, the process may be used in a “recharge” CZ process.

The crystal growing system 200 includes a susceptor 202 supported by a rotatable shaft 204, a crucible assembly 206 that contains a silicon melt 208 from which an ingot 100 is being pulled by a puller cable or shaft 212, and a heating system 214 for supplying thermal energy to the system 200 and maintaining the melt 208. During the crystal pulling process, a seed crystal 216 is lowered by the puller cable or shaft 212 into the melt 208 and then slowly raised from the melt 208. As the seed crystal 216 is slowly raised from the melt 208, silicon atoms from the melt 208 align themselves with and attach to the seed crystal 216 to form the ingot 100.

The crystal growing system 200 also includes a segment chain feed system 262 for feeding monocrystalline segments, such as wing segments 112, into the crucible assembly 206 and/or the melt 208. The system 200 also includes a secondary or auxiliary granular feed system 218 for feeding granular feedstock material 220 into the crucible assembly 206 and/or the melt 208, and a heat shield 222 configured to shield the ingot 100 from radiant heat from the melt 208 to allow the ingot 100 to solidify.

The crucible assembly 206 includes a crucible 224 having a base 226 and a generally annular sidewall 228 extending around the circumference of the base 226. Together, the base 226 and sidewall 228 define a cavity 230 of the crucible 224 within which the melt 208 is disposed. The crucible 224 may be constructed of any suitable material that enables system 200 to function as described herein, including, for example, quartz.

The crucible assembly 206 also includes a fluid barrier shown in the form of a weir 232 that separates the melt 208 into different melt zones. In the example embodiment, the weir 232 separates the melt 208 into an outer melt zone 236 and an inner melt or growth zone 234 from which the ingot 100 is pulled. The weir 232 has a generally annular shape, and has at least one opening defined therein to permit the melt 208 to flow radially inwards towards the growth zone 234. The weir 232 is disposed within the cavity 230 of crucible 224, and creates a circuitous path from the melt zone 236 to the growth zone 234. The weir 232 thereby facilitates melting monocrystalline wing segments 112 and/or granular feedstock material 220 before it reaches an area immediately adjacent to the growing crystal (e.g., the growth zone 234). The weir 232 may be constructed from any suitable material that enables the system 200 to function as described herein, including, for example, quartz. While the example embodiment is shown and described as including a single weir 232, the system 200 may include any suitable number of weirs that enables the system 200 to function as described herein, such as two weirs, three weirs, and four weirs.

The segment chain feed system 262 includes a wing segment chain feeder 264. The chain 124 of monocrystalline wing segments may be introduced or fed into the melt zone 236 from the segment chain feeder 264. The segment chain feeder 264 may include, for example and without limitation, a linear slide or a cable hoist for lifting and placing the chain 124 of monocrystalline wing segments into the melt zone 236. The feed rate of monocrystalline wing segments 112 added to the melt 208 may be independently controlled by a controller (such as the controller 248 described below) based on a pull rate of the ingot 100, a growth rate of the ingot 100, and/or a temperature reduction in the melt 208 resulting from the cooler wing segments 112 being added to the melt 208. In some embodiments, the segment chain feeder 264 includes a release mechanism (not shown) configured to release the last segment 112 of the chain 124 to achieve full melting of the chain 124. In other embodiments, the segment chain feeder 264 has a continuous chaining design, where the existing chain 124 is supported as new wing segments 112 from a wing inventory are automatically added to the chain 124 without modifying the chain feeding rate. Components of the segment chain feeder 264 may be constructed of non-contaminating materials, such as silicon carbide, to prevent contamination of the melt 208.

The granular feed system 218 includes a feeder 240 and a feed tube 242. The granular feed system 218 is provided in addition to the segment chain feed system 262. The granular feed system 218 can be used to augment silicon feed into the melt zone 236. Solid granular feedstock material 220 may be placed into the melt zone 236 from feeder 240 through feed tube 242. The amount of granular feedstock material 220 added to the melt 208 may also be independently controlled by a controller (such as the controller 248, described below) based on the growth rate of the ingot 100, the rate of monocrystalline wing segments 112 added to the melt 208, and the temperature reduction in the melt 208 resulting from the cooler feedstock material 220 being added to the melt 208. In some embodiments, granular feedstock material 220 is added to the melt 208 simultaneously with the chain 124 of monocrystalline wing segments being introduced into the melt 208.

The heat shield 222 is positioned adjacent the crucible assembly 206, and is configured to shield the ingot 100 from radiant heat generated by the melt 208 and the heating system 214 to allow the ingot 100 to solidify. In the example embodiment, the heat shield 222 includes a conical member separating the melt 208 from an upper portion of the system 200, and a central opening defined therein to allow the ingot 100 to be pulled there through. In alternative embodiments, the heat shield 222 may have any suitable configuration that enables the system 200 to function as described herein.

The heating system 214 is configured to melt an initial charge of solid feedstock (such as chunk polysilicon, granular polysilicon, and/or broken wing monocrystalline segments 112), and maintain the melt 208 in a liquefied state after the initial charge is melted. The heating system 214 includes a plurality of heaters 250, arranged at suitable positions about the crucible assembly 206, and a controller 248. In the example embodiment, the heaters 250 have a generally annular shape, and are positioned beneath the crucible 224 and the susceptor 202.

In the example embodiment, the heaters 250 are resistive heaters, although the heaters 250 may be any suitable heating device that enables system 200 to function as described herein. Further, while the example embodiment is shown and described as including two annular heaters 250, the system 200 may include any suitable number of cylindrical or annular heaters 250 that enables the system 200 to function as described herein.

The heaters 250 are connected to the controller 248. The controller 248 controls electric current provided to the heaters 250 to control the amount of thermal energy supplied by heaters 250. The amount of current supplied to each of the heaters 250 by controller 248 may be separately and independently chosen to optimize the thermal characteristics of the melt 208. In the example embodiment, the controller 248 also controls the segment chain feed system 262, the delivery of monocrystalline wing segments 112, the granular feed system 218, the ingot pulling rate, the ingot rotation rate, the crucible rotation rate, and the delivery of granular feedstock material 220 to the melt 208 to control the temperature and level of the melt 208 and the quality of the ingot 100.

A sensor 260, such as, for example, a camera or an optical sensor, provides a continuous or time-sampled measurement of the diameter 110 of the ingot 100, which may be adjusted by varying the pulling rate of the ingot 100. Sensor 260 is communicatively coupled with controller 248. Additional temperature or melt level sensors may be used to measure and provide temperature or melt level feedback to the controller 248 with respect to other areas of the melt 208 that are relevant to the melting of the monocrystalline wing segments 112 and/or feedstock material 220, or in controlling the growing ingot 100. While a single communication lead is shown for clarity, one or more temperature, diameter, or melt level sensor(s) may be linked to the controller 248 by multiple leads or a wireless connection, such as by radio frequency transmission, an infra-red data link or another suitable means.

In use, the crystal pulling system 200 is used to grow monocrystalline ingots from the melt 208 according to the Czochralski method. More specifically, the melt 208 is prepared in the crucible assembly 206 by charging the crucible assembly 206 with feedstock material, such as chunk polycrystalline silicon. The feedstock material is melted in the assembly 206 using heaters 250 to form the melt 208 of semiconductor or solar grade material. Once the feedstock material is sufficiently melted, the seed crystal 216 is lowered into contact with the melt 208 by the puller cable or shaft 212 to initiate crystal growth, and a monocrystalline ingot 100 is grown from the growth zone 234 by subsequently pulling the seed crystal 216 away from the melt 208. The chain 124 of recycled monocrystalline wing segments is introduced at a controlled rate with the chain feeder 264 in a radially outward area of the crucible 224 (e.g., the outer melt zone 236), while the ingot 100 is simultaneously grown from the melt 208 in a radially inward area of the crucible 224 (e.g., the growth zone 234). Granular feedstock material 220 may also be added to the outer melt zone 236 while the chain 124 is introduced into the melt and/or when a new chain 124 of monocrystalline segments is being connected to the chain feeder 264.

Referring now to FIG. 8, a granular silicon production system suitable for recycling monocrystalline wing segments 112 is shown schematically and is indicated generally at 300. The granular silicon production system 300 is used to produce granular silicon pieces 310. The granular silicon pieces 310 produced by the granular silicon production system 300 may be monocrystalline, partially monocrystalline, polycrystalline, or non-crystalline. The granular silicon production system 300 includes a crucible assembly 302 that contains a silicon melt 304 from which melt droplets 306 are formed, and a heating system 308 for supplying thermal energy to the system 300 and maintaining the melt 304. As the melt droplets 306 fall from the bottom of the crucible assembly 302 into a vertical cooling chamber or tower 342 the melt droplets 306 cool and form solid granular silicon pieces 310. The length of the cooling tower 342 may vary based on the application and size of melt droplets 306. In some embodiments, the cooling tower 342 has a length of about 40 feet.

The crucible assembly 302 includes an inner crucible 312 and an outer crucible 320. The inner crucible 312 includes a base 314 and a generally annular sidewall 316 extending around the circumference of the base 314. Together, the base 314 and sidewall 316 define a cavity 318 of the inner crucible 312 within which the melt 304 is disposed. The inner crucible 312 may be constructed of any suitable material that enables system 300 to function as described herein, including, for example quartz.

In the example embodiment, the inner crucible 312 includes an opening 330 formed in the sidewall 316 to permit the melt 304 to flow from the inner crucible 312 into the outer crucible 320. In other embodiments, the inner crucible 312 does not include a hole in the sidewall 316, and the melt 304 flows from the inner crucible 312 into the outer crucible 320 by flowing over the sidewall 316 of the inner crucible 312.

The outer crucible 320 includes a base 322 and a generally annular sidewall 324 extending around the circumference of the base 322. Together, the base 322 and sidewall 324 define a cavity 326 of the outer crucible 320 within which the inner crucible 312 is disposed. The inner crucible 312 is at least partially supported by at least one support wall 334 having a generally annular shape and at least one opening defined therein to permit the melt 304 to flow radially inwards towards a bottom opening 328 in the outer crucible 320. The support wall 334 is disposed within the cavity 326 of the outer crucible 320, and supported by the base 322 of the outer crucible 320. The bottom opening 328 allows the melt 304 to flow out of the outer crucible 320, and into the cooling tower 342. The outer crucible 320 may be constructed of any suitable material that enable system 300 to function as described herein, including, for example quartz. In some embodiments, the inner crucible 312 and/or the outer crucible 320 may be constructed of relatively low quality quartz, such as sintered quartz, due to a relatively small amount of quartz removed during formation of the granular silicon pieces 310 as compared to a Czochralski growth process.

The inner crucible 312 is disposed within the cavity 326 of the outer crucible 320. The inner crucible 312 and the outer crucible 320 may be formed separately from one another, and assembled to form the crucible assembly 302. In alternative embodiments, the crucible assembly 302 may have a unitary construction. That is, the inner crucible 312 and the outer crucible 320 may be integrally formed (e.g., formed from a unitary piece of quartz).

In other embodiments, the outer crucible 320 may be omitted from the silicon granular production system 300. In such embodiments, the system 300 may include one or more tubes that are hermetically connected to the openings 330 in the inner crucible 312 to direct melt flow from the openings 330 to the cooling tower 342.

The system 300 further includes a segment chain feed system 340 for feeding monocrystalline wing segments 112 and/or the chain of monocrystalline wing segments 116 into the crucible assembly 302 and/or the melt 304. Although a single chain 116 is illustrated, more than one chain 116 may be lowered simultaneously into the melt 304 in the inner crucible 312. The rate at which the wing segments 112 are added to the melt 304 may be independently controlled by a controller (such as controller 248, described above with reference to FIG. 7) based on a target flow rate of the melt 304, a target flow rate of melt droplets 306, and/or a temperature reduction in the melt 304 resulting from the cooler wing segments 112 being added to the melt 304.

The heating system 308 is configured to melt an initial charge of solid feedstock (such as monocrystalline wing segments 112), and maintain the melt 304 in a liquefied state after the initial charge is melted. The heating system 308 includes at least one heater 336 arranged at suitable positions about the crucible assembly 302, and a controller, not shown. In the example embodiment, the heater 336 has a generally annular shape, and is positioned around and radially outward of the sidewall 324 of the outer crucible 320.

In the example embodiment, the heater 336 is a resistive heater, although the heater 336 may be any suitable heating device that enables system 300 to function as described herein. Other suitable heating devices include, for example and without limitation, induction heating systems. Further, while the example embodiment is shown and described as including a single heater 336 positioned around and radially outward of the sidewall 324 of the outer crucible 320, the system 300 may include any suitable number of heaters 336 positioned at any suitable location around or beneath the outer crucible 320 to function as described herein.

The heater 336 is connected to a controller, such as the controller 248 shown and described above with reference to FIG. 7. The controller controls electric current provided to the heater 336 to control the amount of thermal energy supplied by heater 336. The amount of current supplied to the heater 336 by the controller may be chosen to optimize the thermal characteristics of the melt 304. In the example embodiment, the controller also controls the segment chain feed system 340 and the delivery of monocrystalline wing segments 112 to the melt 304 to control the temperature of the melt 304. The level of the melt 304 in this embodiment is controlled by the position and size of at least one opening 330 on the side wall 316 of the inner crucible 312.

In use, the granular silicon production system is used to produce granular silicon pieces 310. More specifically, the melt 304 flows 338 from the inner crucible 312 into the outer crucible 320 through at least one opening 330 disposed within the sidewall 316 of the inner crucible 312. In the example embodiment, introducing the chain 124 of monocrystalline wing segments into the inner crucible 312 initiates the flow 338 of the melt 304 from the inner crucible 312 into the outer crucible 320. The melt flows 338 within the cavity 326 to the base 322 of the outer crucible 320, defined at least partially by the sidewall 316 and base 314 of the inner crucible 312. At the bottom opening 328 the melt flow 338 exits the outer crucible 320 and is formed into a stream of discrete melt droplets 306. The melt droplets 306, by gravity, are dropped through a long cooling chamber 342 such that the melt droplets 306 cool and solidify forming granular silicon pieces 310 before reaching the bottom of the cooling chamber 342.

In alternative embodiments, the melt 304 flows from the inner crucible 312 into the outer crucible 320 by overflowing the sidewall 316 of the inner crucible 312. In other alternative embodiments, the inner crucible 312 may include a mechanical escapement, not show, to release the remaining melt 304 below the openings 330 within the sidewall 316 of the inner crucible 312.

During use of the granular silicon production system 300, recycled monocrystalline wing segments 112 are supplied to and melted in the inner crucible 312, while granular silicon pieces 310 are cooled from dropping the melt droplets 306 from the bottom opening 328. In some embodiments, the crucible assembly 302 is not rotated during the process. One limiting factor of the rate at which granular silicon pieces may be formed is the rate at which the melt 304 may be replenished with molten material. In other words, as the drop rate of melt droplets 306 from the bottom opening 328 of the outer crucible 320 increases, the rate at which wing segments 112 are added to the melt 304 must also increase to maintain the melt 304. The granular silicon pieces 310 formed in the granular silicon production system 300 may be fed into the granular feed system 218 as described above with reference to FIG. 7 and the continuous Czochralski method.

In some embodiments, the size of the melt droplets 306 is controlled by controlling a flow of inert gas (e.g., argon) within the cooling tower 342 and/or by opening and closing the opening 328 using an electromagnetic valve (not shown).

During formation of the granular silicon pieces 310, impurities within the melt droplet 306 are concentrated in the tail or “sprout” end of the granular silicon pieces 310 due to impurity segregation during solidification. Accordingly, in some embodiments, the tail or “sprout” end of the granular silicon pieces 310 is removed after formation of the granular silicon pieces 310. Suitable processes for removing the tail end of the granular silicon pieces 310 include cutting and etching processes.

Embodiments of recycling monocrystalline wing segments described herein provide several advantages over known recycling processes. For example, the monocrystalline wing segments are interconnected together and introduced directly into the melt of semiconductor or solar grade material. By recycling whole wing segments, costs and processing time are reduced, and silicon loss is reduced. Labor, energy costs, safety risk, blockage risk, and silicon contamination risks also are all reduced. Additionally, melt zone contamination and system damage is reduced by introducing the chain of wing segments at a controlled rate, as opposed to dropping chunk feedstock material into the melt. Further, an advantage in using recycled monocrystalline wing segments is the segments have been solidification-refined. Thus the segments are purer than general polysilicon feedstock and can improve lifetime performance of the semiconductor or solar grade material.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions and methods without departing from the scope of the invention, it is intended that all matter contained in the above description and shown in the accompanying drawings shall be interpreted as illustrative and not in a limiting sense.

1. A method of recycling monocrystalline segments cut from a monocrystalline ingot of semiconductor or solar grade material, the method comprising:
removing a first monocrystalline segment from the monocrystalline ingot;
connecting the first monocrystalline segment to a second monocrystalline segment to form a chain of monocrystalline segments; and
introducing the chain of monocrystalline segments into a melt of semiconductor or solar grade material.

2. The method of claim 1, wherein the first and second monocrystalline segments are each a curved wing segment.

3. (canceled)

4. The method of claim 1 further comprising forming a first connection interface at a first end of the first monocrystalline segment and a second connection interface at a second end of the second monocrystalline segment, wherein connecting the first monocrystalline segment to the second monocrystalline segment includes interlocking the first connection interface with the second connection interface.

5-6. (canceled)

7. The method of claim 4, wherein forming the first connection interface includes forming:
a first hook at the first end of the first monocrystalline segment, and wherein forming the second connection interface includes forming a second hook at the second end of the second monocrystalline segment, wherein the second hook is configured to matingly engage the first hook to interlock the first monocrystalline segment to the second monocrystalline segment; or
a tongue at the first end of the first monocrystalline segment, and wherein forming the second connection interface includes forming a groove at the second end of the second monocrystalline segment, wherein the groove is configured to matingly engage the tongue to interlock the first monocrystalline segment to the second monocrystalline segment.

8. (canceled)

9. The method of claim 1 further comprising:
forming a first notch at a first end of the first monocrystalline segment;
forming a second notch at the second end of the second monocrystalline segment; and
connecting the first monocrystalline segment to the second monocrystalline segment by inserting a first end of an interconnecting member into the first notch and inserting a second end of the interconnecting member into the second notch such that the first monocrystalline segment is connected to the second monocrystalline segment.

10-13. (canceled)

14. The method of claim 1 further comprising:
preparing the melt in a crucible assembly including an inner crucible and an outer crucible;
initiating a flow of the melt by introducing the chain of monocrystalline segments into the melt, wherein introducing the chain of monocrystalline segments into the melt causes the melt to flow out of the inner crucible and into the outer crucible;
forming a melt droplet from the flow of the melt; and
cooling the melt droplet to form a granular piece of semiconductor or solar grade material.

15. (canceled)

16. The method of claim 14, wherein forming the melt droplet includes flowing the melt through a bottom opening in the outer crucible.

17. The method of claim 14, wherein introducing the chain of monocrystalline segments includes introducing a plurality of the chain of monocrystalline segments into the inner crucible.

18. The method of claim 14 further comprising controlling a flow rate of the melt out of the inner crucible by controlling a chain introduction rate at which the chain of monocrystalline segments is introduced into the melt, wherein the chain introduction rate is based on a target flow rate of the melt.

19. The method of claim 14, wherein cooling the melt droplet includes dropping the melt droplet into a vertical cooling chamber such that the melt droplet cools and solidifies before reaching a bottom of the cooling chamber.

20. A method of growing a monocrystalline ingot from a melt of semiconductor or solar grade material, the method comprising:
preparing the melt of semiconductor or solar grade material in a crucible assembly including a fluid barrier separating the melt into an inner melt zone and an outer melt zone;
pulling a monocrystalline ingot from the inner melt zone; and
introducing a chain of interconnected monocrystalline segments into the outer melt zone to replenish the melt as the ingot is pulled from the melt.

21. The method of claim 20 further comprising forming the chain of interconnected monocrystalline segments by:
removing a first monocrystalline segment from a monocrystalline ingot of semiconductor or solar grade material; and
connecting the first monocrystalline segment to a second monocrystalline segment of semiconductor or solar grade material.

22. The method of claim 20 further comprising controlling a melt level in the crucible assembly by introducing the chain of monocrystalline segments based on a growth rate of the monocrystalline ingot.

23. The method of claim 20 further comprising introducing solid granular feedstock material into the outer melt zone while the chain of interconnected monocrystalline segments is introduced into the outer melt zone.

24-27. (canceled)

28. The method of claim 14, wherein (1) the inner crucible includes a sidewall defining an opening therein, and wherein introducing the chain of monocrystalline segments causes the melt to flow out of the inner crucible through the opening, or (2) the inner crucible includes a sidewall, and wherein introducing the chain of monocrystalline segments causes the melt to flow over the sidewall and out of the inner crucible.

29-32. (canceled)

33. A chain of monocrystalline segments of semiconductor or solar grade material, the chain comprising:
a first monocrystalline segment including a first end, an opposing second end, and a first connection interface disposed at one of the first and second ends; and
a second monocrystalline segment including a first end, an opposing second end, and a second connection interface disposed at one of the first and second ends, wherein the first monocrystalline segment is connected to the second monocrystalline segment via the first and second connection interfaces.

34. (canceled)

35. The chain of monocrystalline segments of claim 33, wherein the first monocrystalline segment and the second monocrystalline segment are curved wing segments cut from at least one monocrystalline ingot of semiconductor or solar grade material.

36. The chain of monocrystalline segments of claim 33, wherein the first connection interface includes a first hook, and the second connection interface includes second hook matingly engaged with the first hook.

37. The chain of monocrystalline segments of claim 33, wherein the first connection interface includes a groove and the second connection interface includes a tongue matingly engaged with the groove.

38. The chain of monocrystalline segments of claim 33, wherein the first connection interface includes a first notch, and the second connection interface includes a second notch, wherein the chain of monocrystalline segments further includes an interconnecting member connected to the first and second monocrystalline segments, the interconnecting member having a first end engaged with the first notch and a second end engaged with the second notch.

39. (canceled)
